(19) United States
(12) Patent Application Publication
(10) Pub. No.: US 2004/0042567 A1
(43) Pub. Date: Mar. 4, 2004

(54) Method of operating a matched filter of a PAM with variable lengths

(76) Inventors: Terng-Yin Hsu, Hu-Wei Chen (TW); Chen-Yi Lee, Hsinchu (TW); Fan-Ming Kuo, Hsinchu (TW)

Correspondence Address: J.C. PATENTS, Suite 250, 4 Venture, Irvine, CA, 92618, US

(21) Appl. No.: 09/818,697

(22) Filed: Mar. 27, 2001

(30) Foreign Application Priority Data
Mar. 2, 2001 (TW) 90104826

(51) Int. Cl. H03D 1/00; H04L 27/06

(52) U.S. Cl. 375/343

(57) ABSTRACT

A method of operating a matched filter of a point access memory (PAM) with variable lengths, suitable for a data storage region to store a received signal and for the matched filter to store a PN sequence in a storage region for reference values. The received signal comprises a plurality of sample data. The method of operating the matched filter of the PAM with variable lengths comprises: storing each sample data in the data storage region; shifting the PN sequence in the storage region for reference values to a corresponding position when all the sample data is stored in the data storage region; and performing a matching operation to match all the stored sample data and the PN sequence that are positioned in the corresponding position.

### CROSS-REFERENCE TO RELATED APPLICATION

This application claims the priority benefit of Taiwan application serial no. 90104826, filed Mar. 2, 2001.

### BACKGROUND OF THE INVENTION

1. Field of Invention

The present invention relates generally to a method of operating a matched filter. More particularly, the present invention relates to a method of operating a matched filter of a point access memory (PAM) with variable lengths.

2. Description of the Related Art

A conventional transmission system has a lot of disadvantages, such as low shifting ability and limitations of the connecting length. As a result, various techniques for wireless transmission have been developed. Among the techniques of wireless transmission, a spread spectrum technique is most often used for sounds and images. In order to get rid of noise interference, a pseudonoise sequence (PN sequence) is added to the spread spectrum technique. The spread spectrum technique comprises two types, a frequency-hopping spread spectrum (FHSS) and a direct-sequence spread spectrum (DSSS).

The DSSS technique has the advantages of data privacy, soft-limited system, anti-jamming and rejecting fading, etc. However, a lot of logic gates are required to operate a chip by the DSSS technique; thus power consumption and area requirements of the chip are increased. A conventional method of handling a device that uses the DSSS technique is to use a shift register. Therefore, the matched filter consumers the most power in the conventional method.

### SUMMARY OF THE INVENTION

The present invention provides a method of operating a matched filter of a point access memory (PAM) with variable lengths. The circuit structure that is provided by the PAM is utilized with a particular operating method to reduce the power consumption.

The present invention provides a method of operating a matched filter of a PAM with variable lengths, suitable for a data storage region to store a receiving signal and for the matched filter to store a PN sequence in a storage region for reference values. The receiving signal comprises a plurality of sample data. The method of operating the matched filter of the PAM with variable lengths comprises the following steps. Each sample data is stored in the data storage region. The PN sequence, which is in the storage region for reference values, is shifted to a corresponding position when every sample data is stored in the data storage region. A matching operation is performed to match all the stored sample data and the PN sequence that are positioned in the corresponding position.

From the above-mentioned preferred embodiment of the present invention, it provides the following advantages. The present invention utilizes a PAM to provide a circuit structure by shifting the PN sequence of the corresponding data instead of shifting the sample data as in the conventional method. Therefore, the amount of data that is shifted is less than in the conventional method.

Both the foregoing general description and the following detailed description are exemplary and explanatory only and are not restrictive of the invention, as claimed.

### BRIEF DESCRIPTION OF THE DRAWINGS

The accompanying drawings are included to provide a further understanding of the present invention, and are incorporated in and constitute a part of this specification. The drawings illustrate embodiments of the invention and, together with the description, serve to explain the principles of the invention. In the drawings,

FIG. 1 is a block diagram of a circuit utilizing a matched filter of a point access memory (PAM) with variable lengths.

FIGS. 2A and 2B are schematic views in accordance with a preferred embodiment of the present invention.

### DESCRIPTION OF THE PREFERRED EMBODIMENTS

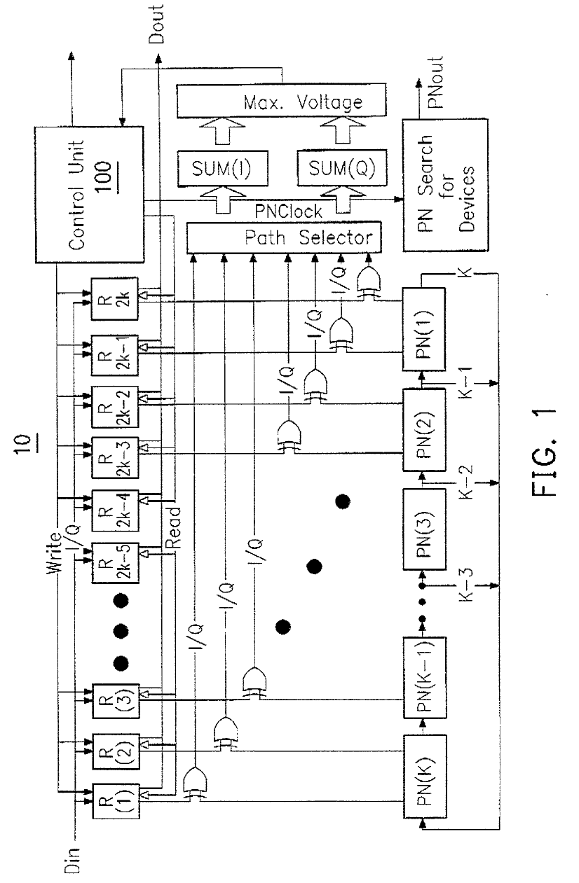

Referring to FIG. 1, a block diagram of a circuit utilizing a matched filter of a point access memory (PAM) with variable lengths is shown. The matched filter 10 receives a receiving signal from the Din and stores a plurality of sample data respectively into data storage locations R1, R2, R3 . . . etc. PN(1), PN(2), PN(3) . . . PN(K) are storage regions of reference values for storing the pseudonoise sequence (PN sequence). Although various methods can be used to operate the circuit structure, not every method can make the best use of a PAM.

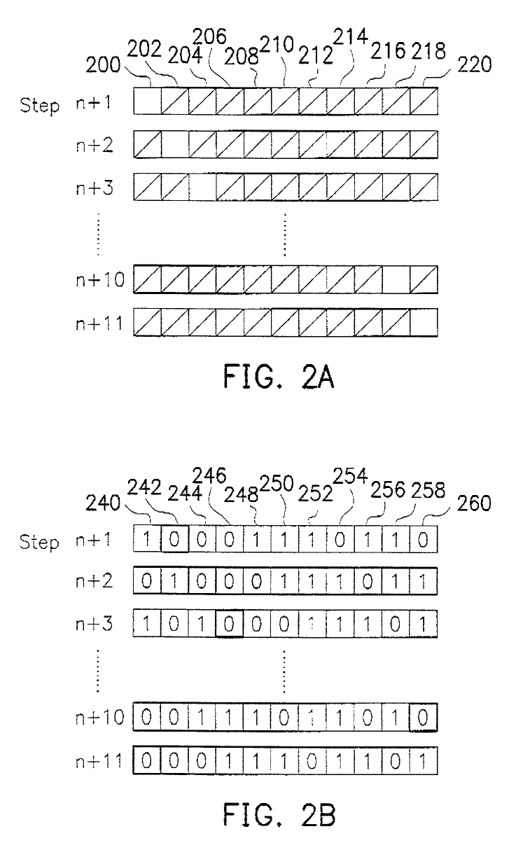

Therefore, the present invention provides an operation method to utilize a matched filter of a point access memory (PAM) with variable lengths, which is shown in FIG. 1. Referring to FIGS. 2A and 2B, schematic views in accordance with a preferred embodiment of the present invention are shown. FIG. 2A is a schematic view of data storage regions for storing each sample data. FIG. 2B is a schematic view of storage regions of reference values for storing a PN sequence. The data storage regions of FIG. 2A comprise data storage blocks 200-220 in which any one of these blocks can store sample data. In FIG. 2B, the storage regions of reference values comprise storage blocks of reference values 240-260. Any one of the storage blocks of reference values 240-260 can store a PN of the PN sequence.

According to the preferred embodiment of the present invention, assume that the width of the data storage regions is 11 (there are 11 storage blocks for reference values), and assume that the length of the PN sequence is also 11. However, the present invention is not limited to the assumed width and length. The number of storage blocks can be varied in accordance with the requirements of those skilled in the art.

Referring to FIG. 2A, assume that a first sample data, which is obtained at step n+1, is stored at one of the data storage blocks, such as block 200. A first PN is obtained and is stored in a storage block of reference value 242 in the corresponding step n+1 of the PN sequence. When a second sample data is obtained in step n+2, it is stored in a data storage block 202 and the first PN is moved to the next block, i.e, the first PN is shifted from the storage block of reference value 242 to storage block of reference value 244 in the step n+2. This technique is carried out throughout the whole process until the step n+11 is reached. In this step, an eleventh sample data is obtained and is stored in the storage block 220, while a first PN is moved to the storage block of reference value 240.

In a conventional method, a shift register is utilized to store sample data. When a sample data is obtained, the position of the stored sample data is moved each time and the position of the PN sequence does not change. Therefore, when a set of shift registers is used to receive an N-chip of PN sequence, sample data is then obtained by K over-sampling frequency, and b-bits of an analog/digital converter (ADC) are transmitted to the shift register. A total number of shift registers NKb are needed to store all the sample data. In the same situation, the present invention utilizes the memory cell in the PAM to store sample data, which is the above-mentioned storage blocks. Only a storage block is needed every time a sample data is obtained. Thus, the power required to shift the number of data b(KN−1) can be reduced.

From the above-mentioned preferred embodiment of the present invention, it provides the following advantages. The present invention utilizes a PAM to provide a circuit structure by shifting the PN sequence of the corresponding data instead of shifting the sample data as in the conventional method. Therefore, the amount of data that is shifted is much less than the conventional method, and the required power for the shifting the data is reduced.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method of operating a matched filter of a point access memory (PAM) with variable lengths, the steps of method comprising:
sequentially receiving a plurality of sample data from a received signal; and
shifting a storage position of a PN sequence according to a storage position of the sample data.

2. The method of claim 1, wherein the sample data are stored according to their sequence without shifting their storage positions.

3. A method of operating a matched filter of a point access memory (PAM) with variable lengths, suitable for a data storage region to store a received signal and for the matched filter to store a PN sequence in a storage region for reference values, wherein the received signal comprises a plurality of sample data, the method comprising:
storing each sample data in the data storage region;
shifting the PN sequence in the storage region for reference values to a corresponding position when all the sample data is stored in the data storage region; and
performing a matching operation to match all the stored sample data and the PN sequence that are positioned in the corresponding position.
